(19) United States
(12) Patent Application Publication
(10) Pub. No.: US 2006/0214718 A1
(43) Pub. Date: Sep. 28, 2006

(54) Voltage level shifter

(75) Inventor: Chuen-Shiu Chen, Hsinchu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Faraday Technology Corp.

(21) Appl. No.: 11/215,104

(22) Filed: Aug. 30, 2005

Related U.S. Application Data
(63) Continuation-in-part of application No. 10/907,241, filed on Mar. 25, 2005.

(51) Int. Cl. H03L 5/00

(52) U.S. Cl. 327/333

(57) ABSTRACT

A voltage level shifter is disclosed, comprising an inverter converting an input signal to an inverted signal, a first NMOS transistor coupled to a first PMOS transistor through a second gating device, and a second NMOS transistor coupled to a second PMOS transistor through a first gating device. Gates of the first and second NMOS transistors are coupled to the input signal and the inverted signal respectively, and gates of the first and second PMOS transistors are coupled to sources of the second and the first NMOS transistor respectively, with the source of the second NMOS transistor acting as the output terminal of the voltage level shifter. The first/second gating device restricts leakage current from the second/first PMOS transistor to the second/first NMOS transistor when the logic state signal is switched, such that the voltage level shifter can be operated with an increased output/input voltage ratio.

### CROSS REFERENCE TO RELATED APPLICATION

This application is a continuation-in-part of U.S. patent application Ser. No. 10/907,241 filed Mar. 25, 2005, which is hereby incorporated by reference.

### BACKGROUND

The invention relates to a voltage level shifter and more particularly to a voltage level shifter with reduced leakage current.

In recent years, COMS-based (complementary metal-oxide-semiconductor) digital logic IC (integrated circuit) technologies have been devised which operate at progressively lower power supply voltages due to the benefits of lower power consumption and faster signal switching times. CMOS logic IC power supply voltages currently available include, for example, 3.3V, 2.5V, 1.8V, and 1.5V. Depending on the application, however, a mix of the various COMS technologies may be used in any particular electronic product, necessitating the use of digital voltage level shifters to translate CMOS signals generated using one power supply to signals based on a different voltage level. Recently many types of CMOS voltage level shifter have been developed to convert a digital signal with a lower voltage swing to a corresponding digital signal with a larger voltage swing.

FIG. 1 is a conventional voltage level shifter, utilizing a PMOS transistor P3 and a NMOS transistor N3 as an inverter 10 between a first voltage source VCC1 and a reference voltage source (such as ground in the figure), a PMOS transistor P2 connected in series with a NMOS transistor N2 between a second voltage source VCC2 and the reference voltage source, a NMOS transistor N1 between the output terminal of the inverter 10 and the gate of the transistor P2 with the gate connected to the first voltage source VCC1, and a PMOS transistor P1 between the second voltage source VCC2 and the gate of the transistor P2, wherein the gate of the PMOS transistor P1 is connected with the drains of the transistors P2 and N2 outputting an output signal VOUT. The first voltage source VCC1 and the reference voltage source, typically, are set equal to the high logic level and the low logic level of the input signal VIN respectively, and the second voltage source VCC2 is set higher than the high logic level of the input signal VIN so that the high logic level of the output signal VOUT is higher than that of the input signal VIN.

When the voltage level shifter is started, if the first voltage source VCC1 is turned on prior to the second voltage source VCC2, the first voltage source VCC1 is momentarily on while the second voltage source VCC2 is off. As the input signal VIN is still maintained at low logic level, transistors P3, N1, and P1 are all turned on in response. A leakage current I is thus generated from the first voltage source VCC1 through the transistors P3, N1 and P1; to the second voltage source VCC2, which is undesirable and results in unnecessary power dissipation.

In view of such problems as shown in a conventional voltage level shifter in FIG. 1, applicant of the present invention has proposed an improved voltage level shifter as shown in FIG. 2. The improved voltage level shifter, by modifying interconnections of the transistors in FIG. 1, produces no paths for leakage current, thereby reducing the power consumption.

However, if the logic state of the input signal VIN-turns from high to low, or the voltage of the same changes to the ground level, the transistor N1 is turned off accordingly. Since the output signal VOUT is initially at a high level VCC2, the transistor P1 is also off. As a result, the voltage at node 22 or the gate of the transistor P2 is not driven to any particular level and therefore floats. Concurrently, the input signal VIN at ground level turns the transistor P3 on and transistor N3 off, pulling up the voltage of the inverted signal VINI to VCC1, further turning on the transistor N2. As a result, the voltage of the output signal VOUT is pulled down. However, since the transistor P2 is not turned-off, and the level of the inverted VINI is VCC1, which is lower than VCC2 and cannot adequately turn on the transistor N1, leakage current from the transistor P2 to N1 is generated, preventing the voltage of the output signal VOUT from being pulled down close to the ground level promptly.

When the voltage of the output signal VOUT falls, the transistor P1 begins to turn on, driving the voltage at node 22 to VCC2. In response, the transistor P2 begins to turn off, reducing leakage current, and further lowering the voltage of the output signal VOUT. With the falling of the voltage of the output signal VOUT, the leakage current continues decreasing. Finally, the level of the output signal VOUT is close to the ground level.

FIGS. 3A, 3B and 3C compare the simulated waveforms of the output signal VOUT and the input signal VIN for the level shifter in FIG. 2, where the VCC1 is 1.8V and VCC2 is 2.5V. FIGS. 3A, 3B, and 3C corresponds to combinations of transistors PTNT (typical PMOS, typical NMOS, 25 C), PFNS (fast PMOS, slow NMOS, 125 C), and PSNF (slow PMOS, fast NMOS, —40 C), respectively. It is observed that the falling edge of the output signal VOUT floats and delays compared to that of the input signal VIN.

FIGS. 4A, 4B, and 4C compare simulated waveforms of the output signal VOUT and the input signal VIN for the level shifter in FIG. 2, where VCC1 is still 1.8V while VCC2 is increased to 2.5V, and also compare three combinations of the transistors including PTNT, PFNS, and PSNF, showing that floating and delay of the falling edge of output signal VOUT are considerable.

As explained, the cause is a leakage current from the second voltage source VCC2 through the transistor P2 to N2 at the moment when the voltage of the input signal VIN changes from high to low, preventing the voltage of the output signal VOUT from being pulled down close to the ground level promptly. With the increased VCC2, leakage current also increases, leading to a more serious floating and delaying of the falling edge of the output signal VOUT. Accordingly, the voltage level cannot be operated with a larger output/input voltage ratio.

Next, the logic state of the input signal VIN changes from high to low, or the voltage of the same changes to VCC1. In response, the transistor N1 turns on, driving the voltage at node 22 to ground level, further turning on the transistor P2. Since the output signal VOUT is initially at the ground level, the transistor P1 is also on. With both the transistors P1 and N1 on, and the level of the input signal VCC1 lower than VCC2, leakage current is generated accordingly from the second voltage source VCC2 through the transistor P1 to N1, preventing the voltage at node 22 from being pulled down close to the ground level promptly. Concurrently, the input signal VIN at VCC1 turns off the transistor P3 and the transistor N3 on, pulling down the voltage of the inverted signal VINI to the ground level, further turning off the transistor N2. Since VCC1 is substantially equal to the high level of the input signal VIN, the level of the inverted signal VINI is low enough to turn off the transistor N2 to an adequate extent. As a result, despite incomplete turning on of the transistor P2, the voltage of the output signal VOUT is pulled up enough near to VCC2 in a short time.

FIGS. 3A, 3B, 3C and FIGS. 4A, 4B, 4C show no obvious floating or delay at the rising edge of the output signal VOUT.

When the voltage of the output signal VOUT rises, the transistor P1 begins to turn off, decreasing the leakage current, further pulling down the voltage at node 22 nearer to the ground level. In response, the extent of the turning on of the transistor P2 increases, driving the level of the output signal VOUT closer to VCC2. With the rise in the voltage of the output signal VOUT, the extent of the turning off of the transistor P1 continues increasing, resulting in continued decrease in leakage current and continued increase in the turning on of the transistor P2. Finally, the level of the output signal VOUT is closer to the ground.

In summary, what is called for is a voltage level shifter generating no leakage current when the logic state of the input signal is switched, improving the output/input voltage ratio, and none when the voltage sources are turned on sequentially, resulting in reduce of power consumption.

### SUMMARY OF THE INVENTION

The invention provides a voltage level shifter utilizing gating devices to limit leakage current occurring at the moment when the logic state of the input signal is switched. Floating and delay of the output signal are solved, resulting in a voltage level shifter that can be operated with an increased output/input voltage ratio. In addition, the voltage level shifter generates no leakage current when stared, thereby reducing the power consumption.

The voltage level shifter of the invention comprises an inverter between a first voltage source and a reference voltage source converting an input signal to an inverted signal, a first NMOS transistor and a first PMOS transistor between a second voltage source and the reference voltage source, the first NMOS transistor coupled to the first PMOS transistor through a second gating device, a second NMOS transistor and a second PMOS transistor coupled between a the first voltage source and the reference voltage source, the second NMOS transistor coupled to the second PMOS transistor through a first gating device. The gates of the first and the second NMOS transistors receive the input signal and the inverted signal respectively. The gates of the first and the second PMOS transistors are coupled to the drains of the second and the first NMOS transistor respectively. The drain of the second NMOS transistor acts as the output terminal of the voltage level shifter.

The first gating device turns off when the voltage of the input signal is at a low level, and turns on when the voltage of the input is at a high level, thus limiting leakage current from the second PMOS transistor to the second NMOS transistor when the input signal is switched from the high level to the low level. Floating and delay of the output signal at the falling edge are thus eliminated. Similarly, the second gating device turns on when the voltage of the input signal is at a low level and turns off when the voltage of the input is at a high level, thus limiting the leakage current flowing from the first PMOS transistor to the first NMOS transistor when the input signal is switched from the low level to the high level. The floating and delay of the output signal at the rising edge are thus eliminated. The voltage level shifter, in the absence of leakage current, can thus be operated with an increased output/input voltage ratio.

### BRIEF DESCRIPTION OF THE DRAWINGS

The foregoing and other advantages and features of the invention will become more apparent from the detailed description of exemplary embodiments of the invention given below with reference to the accompanying drawings in which:

FIG. 1 illustrates a circuit diagram of a conventional voltage level shifter;

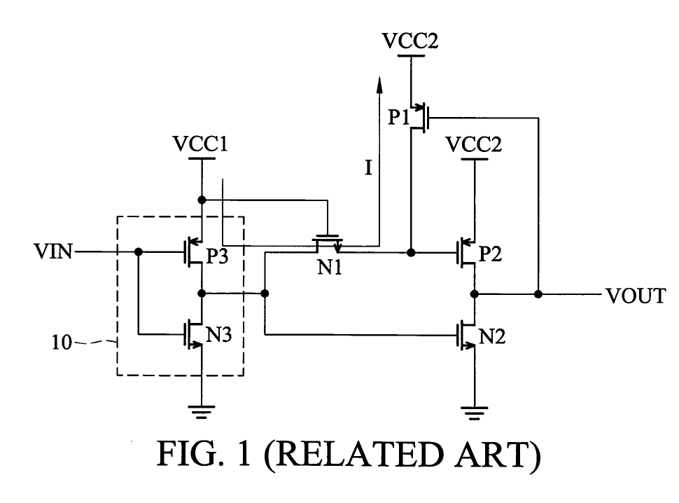

FIG. 2 shows a circuit diagram of a voltage level shifter in accordance with an embodiment of the preceding invention of the present invention;

FIGS. 3A, 3B, and 3C illustrate simulated waveforms of the input signal and the output signal for the voltage level shifter in FIG. 2 implemented with different combinations of transistors;

FIGS. 4A, 4B, and 4C illustrate simulated waveforms of the input signal and the output signal for the voltage level shifter in FIG. 2 implemented with different combinations of transistors and with increased voltage source;

FIG. 5 shows a circuit diagram of a voltage level shifter in accordance with one embodiment of the present invention;

FIGS. 6A, 6B, and 6C illustrate simulated waveforms of the input signal and the output signal for the voltage level shifter of the invention implemented with different combinations of transistors;

FIGS. 7A, 7B, and 7C illustrate simulated waveforms of the input signal and the output signal for the voltage level shifter of the invention implemented with different combinations of transistors and with increased voltage source;

FIG. 8 is a circuit diagram of a voltage level shifter in accordance with another embodiment of the invention;

### DETAILED DESCRIPTION

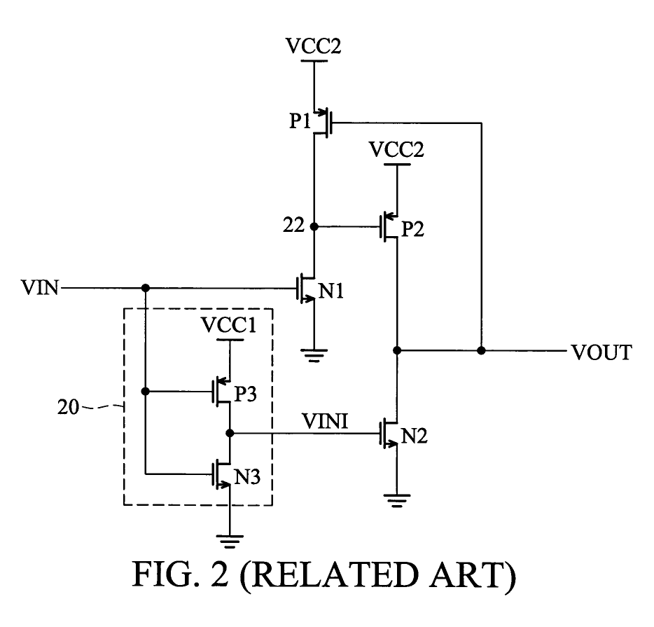

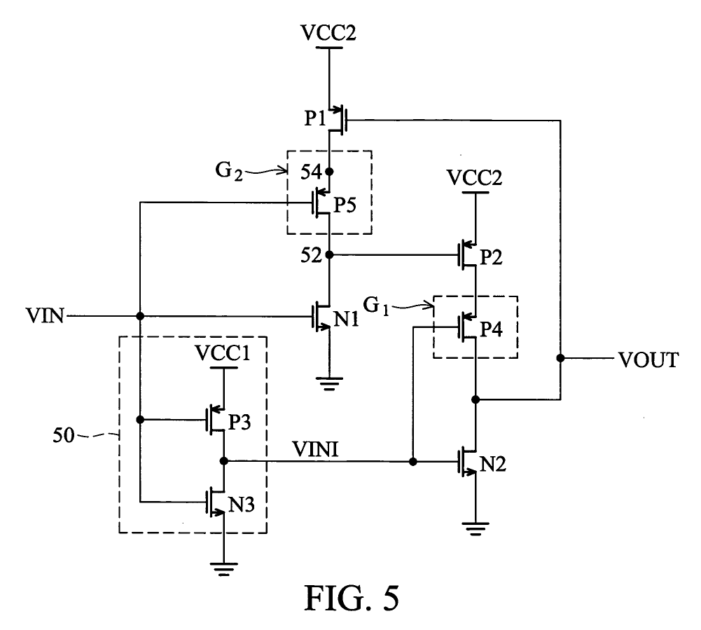

FIG. 5 shows a voltage level shifter in accordance with an embodiment of the invention. It is noted that with the exception of a first gating device between transistor P2 and transistor N2, and a second gating device between transistor P1 and transistor N1, other parts of the circuit are all the same as FIG. 2. In the embodiment, the first gating device G1 is implemented with a PMOS transistor P4 with the gate coupled to the inverted signal VINI, while the second gating device is implemented with a PMOS transistor P5 with the gate coupled to the input signal VIN.

If the logic state of the input signal VIN turns from high to low, or the voltage of the same changes to ground level, the transistor N1 is turned off and the transistor P5 turned on. Since the output signal VOUT is initially at a high level VCC2, the transistor P1 is also off. As a result, both the voltages at node 54 and at node 52 float. Concurrently, the low-level input signal VIN turns the transistor P3 on and transistor N3 off, pulling up the voltage of the inverted signal VINI to VCC1, further turning on the transistor N2. Resultingly, the voltage of the output signal begins to approach ground level. It should be noted that when the transistor P2 is not turned off and the level of the inverted VINI is VCC1, insufficient to turn on the transistor N2 to an adequate extent for it is lower than VCC2, leakage current is generated from the second voltage source VCC2 through P2 to N2, preventing the voltage of the output signal VOUT from approaching the ground level, as in FIG. 2. In the invention, the additional transistor P4 turns off, limiting leakage current from the second voltage source VCC2 through P2 to N2, such that the output signal VOUT turns from high to low faster than the level shifter in FIG. 2 when the input signal turns from high to low.

When the voltage of the output signal VOUT falls, the transistor P1 begins to turn on, driving the voltage at node 52 and 52 to VCC2. In response, the transistor P2 begins to turn off, reducing leakage current, and further lowering the voltage of the output signal VOUT. With the falling of the voltage of the output signal VOUT, the leakage current continues decreasing. Finally, the level of the output signal VOUT is close to the ground level.

Next, the logic state of the input signal turns from low to high, or the level of the same changes to VCC1. In response, the transistor N1 turns on and the transistor P5 turns off, driving the voltage at node 22 to the ground level, further turning on the transistor P2. Since the output signal VOUT is initially at the ground level, the transistor P1 is also on. It should be noted that because the transistor P1 is on and the level of the input signal VIN is VCC1, which is lower than VCC2 and insufficient to turn on the transistor N1 to an adequate extent, in the voltage level shifter without the transistor P5 as shown in FIG. 2, a leakage current is generated from the second voltage source VCC2 through P1 to N1, preventing the voltage at node 52 from being pulled down close to the ground level promptly. In the invention, however, the additional transistor P5 turns off, limiting the leakage current from the voltage source VCC2 through P1 to N1. As a result, the voltage at node 52 in the embodiment gets nearer to the ground level than the voltage at node 22 in FIG. 2. Concurrently, the level VCC1 of the input signal VIN turns the transistor P3 off and the transistor N3 on, pulling down the voltage of the inverted signal VINI to the ground level, further turning off the transistor N2. As mentioned in FIG. 2, since VCC1 is substantially equal to the high level of the input signal VIN, the level of the inverted signal VINI is low enough to turn off the transistor N2 to an adequate extent, and the voltage of the output signal VOUT is pulled-up near enough to VCC2, even without the additional transistor P5. With the addition of the transistor P5, the voltage at node 52 gets nearer to the ground level, increasing the extent of the turning on of the transistor P4. As a result, the output signal VOUT in the embodiment turns from low to high faster than the level shifter in FIG. 2 when the input signal turns form low to high.

As the voltage of the output signal VOUT rises, the transistor P1 begins to turn off, decreasing the leakage current, and further pulling down the voltage at node 52 nearer to the ground level. In response, the turning on of the transistor P2 increases, driving the level of the output signal VOUT closer to VCC2. With the rising voltage of the output signal VOUT, the turning off of the transistor P1 continues increasing, resulting in the continued decrease in leakage current and continued increase in the turning on of the transistor P2. Finally, the level of the output signal VOUT is closer to the ground.

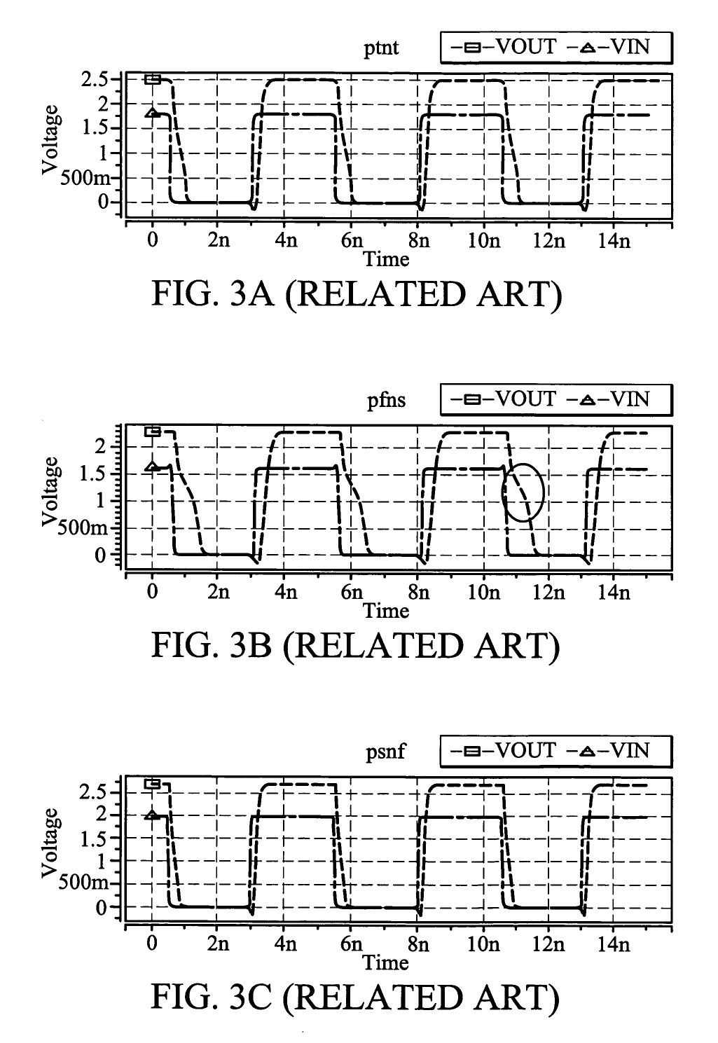

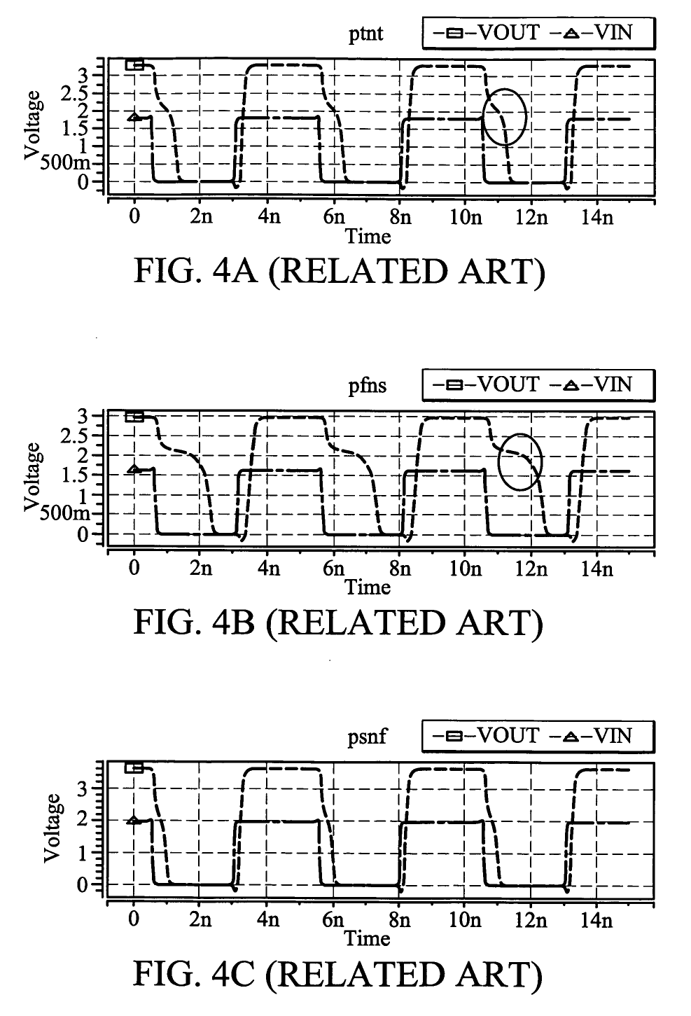

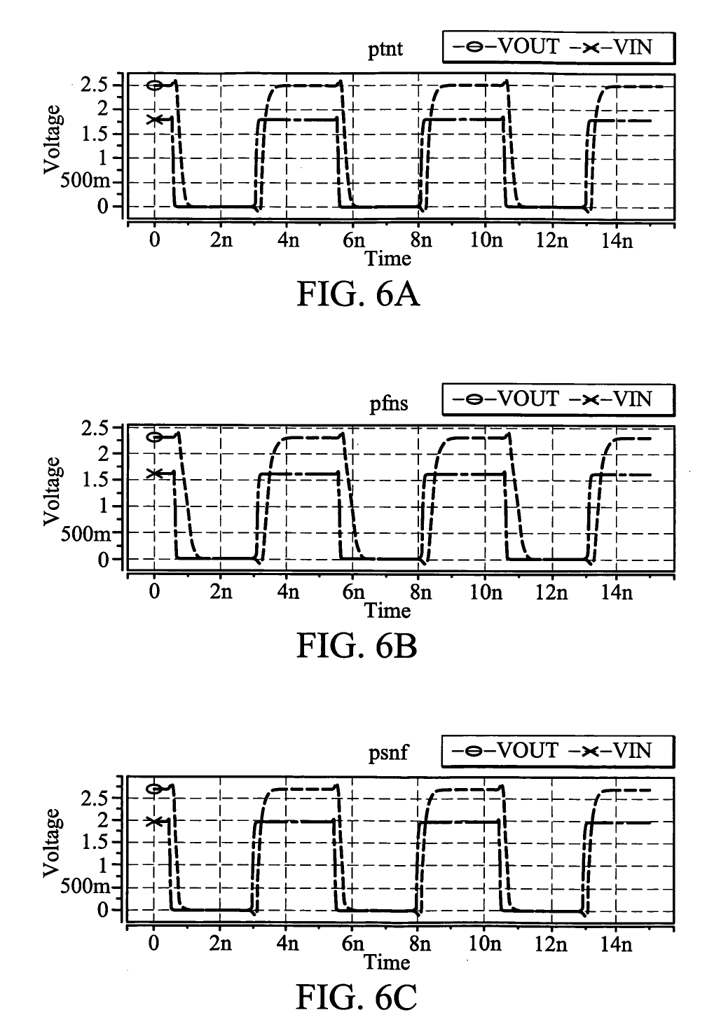

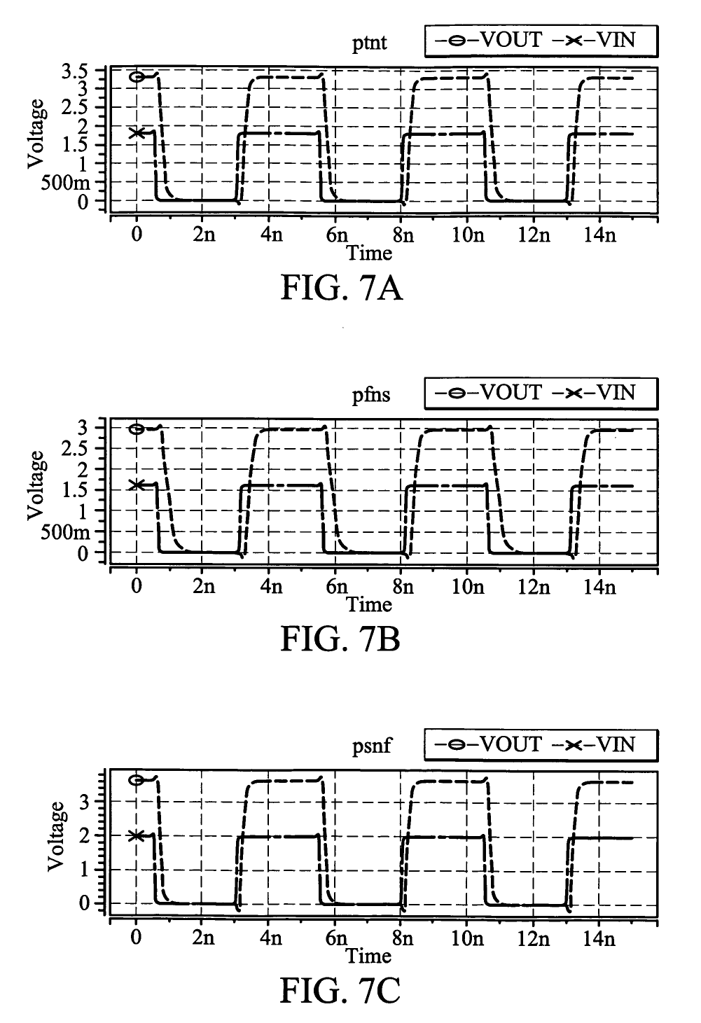

FIGS. 6A, 6B, 6C and FIGS. 7A, 7B, 7C compare the simulated waveforms of the output signal VOUT and the input signal VIN for the level shifter of the embodiment, where the VCC1 is still 1.8V while VCC2 are 2.5V and 3.3V respectively, and further compare three combinations of the transistors including PTNT, PFNS, and PSNF. As shown in FIGS. 6A, 6B, 6C and FIGS. 7A, 7B, 7C, the floating or delay at the falling edges of the output signal VOUT are eliminated. Even though in FIGS. 3A, 3B, 3C and FIGS. 4A, 4B, 4C no obvious floating or delay occurs at the rising edges of the output signal VOUT, it still can be noted that in FIGS. 6B and 7B, the timing of the output signal VOUT is closer to that of the input signal VIN than in FIGS. 3B and 4B.

As shown in FIG. 5, when the voltage level shifter starts, the voltage sources VCC1 and VCC2 are also turned on sequentially. As well, transistor N1, as in FIG. 2, has one terminal grounded. Thus when the voltage level shifter starts and the input signal VIN is still low, even though the voltage source VCC1 has been turned on while the voltage source VCC2 is turned off, no leakage current is generated.

In the voltage level shifter of the invention, when the voltage level shifter starts and the voltage sources VCC1 and VCC2 are turned on sequentially, no leakage current is generated, such that power consumption is improved. In addition, when the input signal changes logic state, leakage current is reduced. With the reduced leakage current, he floating and delaying of the output voltage are avoided. The voltage level shifter of the invention can thus operate with an increased output/input voltage ratio.

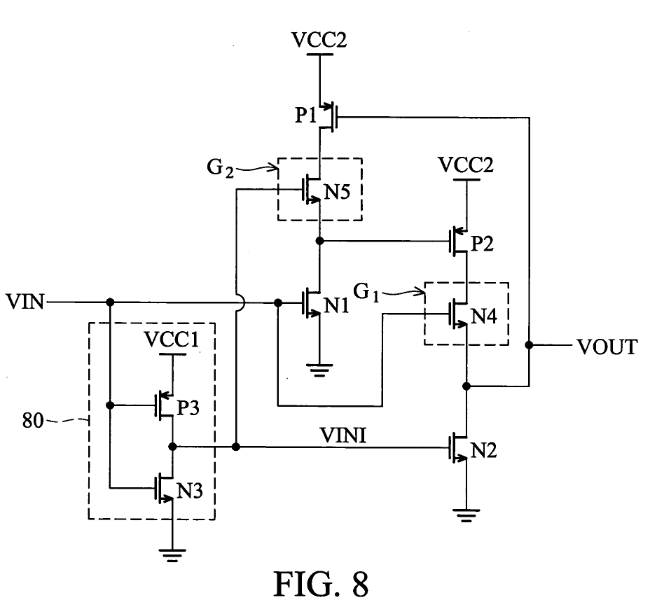

FIG. 8 shows a voltage level shifter in accordance with another embodiment of the present invention. It is noted that except the PMOS transistor P4 making up the first gating device G1 being replaced with a NMOS transistor N4, and the transistor P5 making up the second gating device replaced with a NMOS transistor N5, all other components and coupling relationships thereof are the same as those in FIG. 5. Here, the first gating device turns off when the input signal is low and turns on when the input signal is high, limiting leakage current from the transistor P2 to the transistor N2. NMOS transistor N4 with its gate coupled to the input signal VIN can thus achieve the same function as the transistor P4. Similarly, the second gating device turns on when the input signal is low and turns off when the input signal is high, limiting leakage current from the transistor P1 to the transistor N1. NMOS transistor N5 with its gate coupled to the inverted signal VINI can thus achieve the same function as the transistor P5.

While the invention has been described by way of example and in terms of the preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A voltage level shifter, comprising:
an inverter between a first voltage source and a reference voltage source converting an input signal to an inverted signal;
a first transistor, a second source/drain of which is coupled with a second voltage source and a gate of which is coupled with the output terminal of the voltage level shifter;
a second transistor, a first source/drain of which is coupled with a first source/drain of the first transistor, a second source/drain of which is coupled with the reference voltage source, and a gate of which is coupled with the input signal;
a third transistor, a second source/drain of which is coupled with the second voltage source and a gate of which is coupled with the first source/drain of the second transistor;
a fourth transistor, a first source/drain of which is coupled with the first source/drain of the third transistor and acts as the output terminal of the voltage level shifter, a second source/drain of which is coupled with the reference voltage source, and a gate of which is coupled with the inverted signal;
a first gating device coupled between the third transistor and the fourth transistor, turned off when the input signal is at a first level and turned on when the input signal is at a second level;
wherein the first transistor and the third transistor are first type transistors, and the second transistor and the fourth transistor are second type transistors.

2. The voltage level shifter as claimed in claim 1, wherein the first gating device limits current that flows from the second voltage source through the third transistor into the fourth transistor.

3. The voltage level shifter as claimed in claim 1, further comprising a second gating device coupled between the first transistor and the second transistor, turned on when the input signal is at the first level and turned off when the input signal is at the second level.

4. The voltage level shifter as claimed in claim 3, wherein the second gating device limits current that flows from the second voltage source through the first transistor into the second transistor.

5. The voltage level shifter as claimed in claim 1, wherein the inverter is a complementary MOS pair which comprises a first type MOS transistor and a second type MOS transistor connected in series.

6. The voltage level shifter as claimed in claim 2, wherein the first gating device is a first type MOS transistor, with the gate connected with the inverted signal, the first source/drain connected with the first source/drain of the fourth transistor, and the second source/drain connected with the first source/drain of the third transistor.

7. The voltage level shifter as claimed in claim 2, wherein the first gating device is a second type MOS transistor, with the gate connected with the input signal, the first source/drain connected with the first source/drain of the third transistor, and the second source/drain connected with the first source/drain of the fourth transistor.

8. The voltage level shifter as claimed in claim 4, wherein the second gating device is a first type MOS transistor, with the gate connected with the input signal, the first source/drain connected with the first source/drain of the second transistor, and the second source/drain connected with the first source/drain of the first transistor.

9. The voltage level shifter as claimed in claim 4, wherein the second gating device is a second type MOS transistor, with the gate connected with the inverted signal, the first source/drain connected with the first source/drain of the first transistor, and the second source/drain connected with the first source/drain of the second transistor.
